(19) United States
(12) Patent Application Publication
(10) Pub. No.: US 2014/0374882 A1
(43) Pub. Date: Dec. 25, 2014

(54) Semiconductor Device with Recombination Centers and Method of Manufacturing

(71) Applicant: Infineon Technologies Austria AG, Villach (AT)

(72) Inventors: Ralf Siemieniec, Villach (AT); Hans-Joachim Schulze, Taufkirchen (DE); Stefan Gamerith, Villach (AT); Hans Weber, Bayerisch Gmain (DE)

(21) Appl. No.: 13/923,719

(22) Filed: Jun. 21, 2013

(51) Int. Cl. H01L 29/04; H01L 21/265

(52) U.S. Cl. CPC H01L 29/04; H01L 21/265
USPC 257/618; 438/473

(57) ABSTRACT

A semiconductor device includes a semiconductor portion with one or more impurity zones of the same conductivity type. A first electrode structure is electrically connected to the one or more impurity zones in a cell area of the semiconductor portion. At least in an edge area surrounding the cell area a recombination center density in the semiconductor portion is higher than in an active portion of the cell area.

### BACKGROUND

In a conductive state of a power semiconductor device a forward biased power diode or a forward biased body diode of a field effect transistor injects charge carriers into a drift layer. When the pn junction changes to a blocking state these charge carriers are drained off and induce a recovery current that contributes to the dynamic switching losses of the semiconductor device. Some approaches provide introducing platinum impurities into the drift layer to reduce the reverse recovery charge Qrr by reducing the charge carrier lifetime. It is desirable to improve transistor parameters.

### SUMMARY

According to an embodiment a semiconductor device includes a semiconductor portion with one or more impurity zones of the same conductivity type. A first electrode structure is electrically connected to the one or more impurity zones in a cell area of the semiconductor portion. At least in an edge area surrounding the cell area a recombination center density in the semiconductor portion is higher than in an active portion of the cell area.

According to another embodiment a semiconductor device includes a semiconductor portion with crystal lattice vacancies and atoms of a metallic recombination element gettered at the crystal lattice vacancies. At least in a fraction of the semiconductor portion a density of crystal lattice vacancies exceeds 10¹³ cm⁻³.

Another embodiment refers to a method of manufacturing a semiconductor device. In at least portions of the semiconductor substrate crystal lattice vacancies are generated, wherein a density of the crystal lattice vacancies exceeds 10¹³ cm⁻³. After generating the crystal lattice vacancies and before applying a thermal budget annealing the crystal lattice vacancies, atoms of a metallic recombination element are introduced into the semiconductor substrate.

Another embodiment refers to a further method of manufacturing a semiconductor device. An auxiliary mask is provided covering at least a portion of a cell area and exposing at least an edge area of a semiconductor die included in a semiconductor substrate. The edge area surrounds the cell area. Recombination centers are provided in portions of the semiconductor substrate exposed by the auxiliary mask.

Those skilled in the art will recognize additional features and advantages upon reading the following detailed description and on viewing the accompanying drawings.

### BRIEF DESCRIPTION OF THE DRAWINGS

The accompanying drawings are included to provide a further understanding of the invention and are incorporated in and constitute a part of this specification. The drawings illustrate the embodiments of the present invention and together with the description serve to explain principles of the invention. Other embodiments of the invention and intended advantages will be readily appreciated as they become better understood by reference to the following detailed description.

FIG. 1 is a schematic cross-sectional view of a section of a semiconductor portion in accordance with an embodiment providing a higher recombination center density in an edge area.

FIG. 2A is a schematic cross-sectional view of a fraction of a semiconductor portion in accordance with an embodiment providing a semiconductor diode with an increased recombination center density in an edge area.

FIG. 2B is a schematic cross-sectional view of a fraction of a semiconductor portion in accordance with an embodiment providing an IGFET (insulated gate field effect transistor) with an increased recombination center density in an edge area.

FIG. 2C is a schematic cross-sectional view of a fraction of a semiconductor portion in accordance with an embodiment providing a IGBT (insulated gate bipolar transistor) with an increased recombination center density in an edge area.

FIG. 3 shows a schematic diagram illustrating a vertical recombination center density profile according to an embodiment.

FIG. 4 is a schematic planar cross-sectional view of a semiconductor device in accordance with an embodiment providing an increased recombination center density in inactive portions of the cell area.

FIG. 5 is a schematic cross-sectional view of a portion of a semiconductor device with an increased density of crystal lattice vacancies according to an embodiment providing contact grooves and contact zones.

FIG. 6A is a schematic cross-sectional view of a portion of a semiconductor diode with an increased density of crystal lattice vacancies according to another embodiment.

FIG. 6B is a schematic cross-sectional view of a portion of a super junction IGFET with an increased density of crystal lattice vacancies according to another embodiment.

FIG. 6C is a schematic cross-sectional view of a portion of a super junction IGBT with an increased density of crystal lattice vacancies according to a further embodiment.

FIG. 6D is a schematic cross-sectional view of a portion of a vertical IGFET with an increased density of crystal lattice vacancies gettering atoms of a metallic combination element according to a further embodiment.

FIG. 7A is a schematic cross-sectional view of a portion of a semiconductor substrate for illustrating a method of manufacturing a semiconductor device according to an embodiment increasing the crystal lattice vacancy density by an anneal in a nitrogen atmosphere after forming contact grooves.

FIG. 7B is a schematic cross-sectional view of the semiconductor substrate of FIG. 7A after introducing impurities for forming contact zones.

FIG. 7C is a schematic cross-sectional view of the semiconductor substrate of FIG. 7B after an RTP (rapid thermal process) for annealing implant damages.

FIG. 7D is a schematic cross-sectional view of the semiconductor substrate of FIG. 7C after introducing atoms of a metallic recombination element.

FIG. 7E is a schematic cross-sectional view of a semiconductor device manufactured according to the method illustrated in FIGS. 7A to 7D.

FIG. 8A is a schematic cross-sectional view of a portion of a semiconductor substrate for illustrating a method of manufacturing a semiconductor device according to an embodiment providing the crystal lattice vacancies before implanting contact zones in a stage after providing contact grooves.

FIG. 8B is a schematic cross-sectional view of the semiconductor substrate of FIG. 8A after providing an impurity mask on sidewalls of the contact grooves in a process generating crystal lattice vacancies.

FIG. 8C is a schematic cross-sectional view of the semiconductor substrate of FIG. 8C after implanting contact zones using the impurity mask.

FIG. 8D is a schematic cross-sectional view of the semiconductor substrate of FIG. 8C after introducing atoms of a metallic recombination element.

FIG. 9A is a schematic cross-sectional view of a portion of a semiconductor substrate for illustrating a method of manufacturing a semiconductor device according to an embodiment increasing the crystal lattice vacancy density in an edge area after etching cell trenches.

FIG. 9B is a schematic cross-sectional view of the semiconductor substrate of FIG. 9A during an implant into the edge area using an implant mask.

FIG. 9C is a schematic cross-sectional view of the semiconductor substrate of FIG. 9B after introducing atoms of a noble gas using the implant mask of FIG. 9B.

FIG. 9D is a schematic cross-sectional view of a semiconductor device manufactured according to the method illustrated in FIGS. 9A to 9C.

### DETAILED DESCRIPTION

In the following detailed description, reference is made to the accompanying drawings, which form a part hereof, and in which are shown by way of illustrations specific embodiments in which the invention may be practiced. It is to be understood that other embodiments may be utilized and structural or logical changes may be made without departing from the scope of the present invention. For example, features illustrated or described for one embodiment can be used on or in conjunction with other embodiments to yield yet a further embodiment. It is intended that the present invention includes such modifications and variations. The examples are described using specific language which should not be construed as limiting the scope of the appending claims. The drawings are not scaled and are for illustrative purposes only. For clarity, the same elements have been designated by corresponding references in the different drawings if not stated otherwise.

The terms “having”, “containing”, “including”, “comprising” and the like are open and the terms indicate the presence of stated structures, elements or features but not preclude additional elements or features. The articles “a”, “an” and “the” are intended to include the plural as well as the singular, unless the context clearly indicates otherwise.

The term “electrically connected” describes a permanent low-ohmic connection between electrically connected elements, for example a direct contact between the concerned elements or a low-ohmic connection via a metal and/or highly doped semiconductor. The term “electrically coupled” includes that one or more intervening element(s) adapted for signal transmission may be provided between the electrically coupled elements, for example elements that are controllable to temporarily provide a low-ohmic connection in a first state and a high-ohmic electric decoupling in a second state.

The figures illustrate relative doping concentrations by indicating “−” or “+” next to the doping type “n” or “p”. For example, “n” means a doping concentration that is lower than the doping concentration of an “n”-doping region while an “n⁺”-doping region has a higher doping concentration than an “n”-doping region. Doping regions of the same relative doping concentration do not necessarily have the same absolute doping concentration. For example, two different “n”-doping regions may have the same or different absolute doping concentrations.

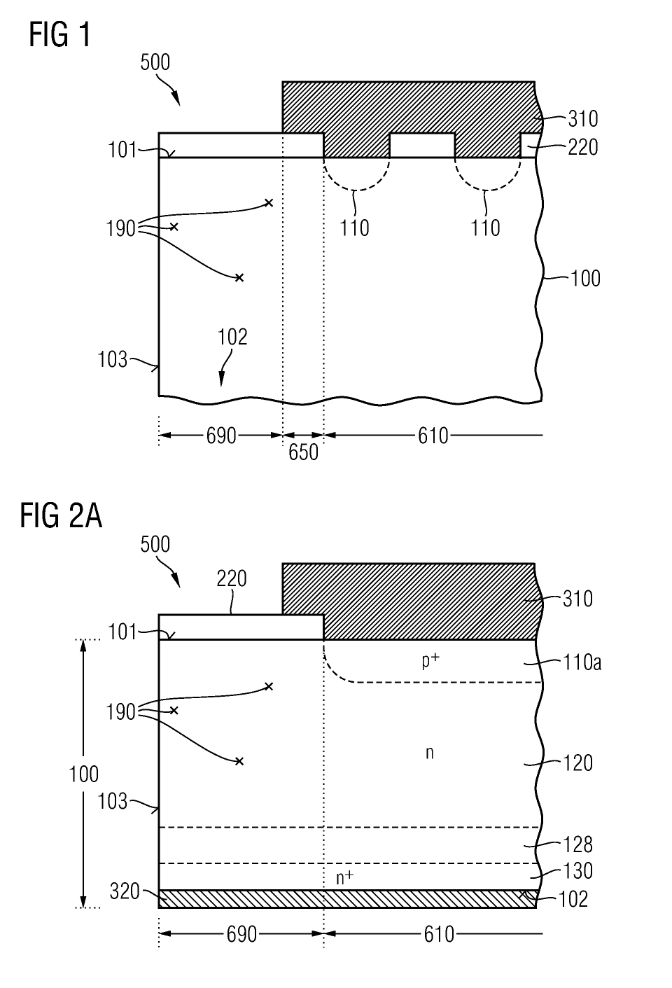

FIG. 1 shows a semiconductor device 500 with a semiconductor portion 100 having a first surface 101 and a second surface 102 parallel to the first surface 101. The semiconductor portion 100 is provided from a single-crystalline semiconductor material, for example silicon (Si).

A distance between the first and second surfaces 101, 102 may be at least 40 μm, for example at least 175 μm. The semiconductor portion 100 may have a rectangular shape with an edge length in the range of several millimeters or a circular shape with a diameter of several millimeters. The normal to the first and second surfaces 101, 102 defines a vertical direction and directions orthogonal to the normal direction and parallel to the first and second surfaces 101, 102 are lateral directions. An outer surface 103 is tilted, e.g., perpendicular, to the first and second surfaces 101, 102 and connects the first and second surfaces 101, 102.

At least one impurity zone 110 extends from the first surface 101 into the semiconductor portion 100. Each of the impurity zones 110 have the same conductivity type, which may be the n-type or the p-type. The impurity zones 110 are electrically connected with a first electrode structure 310 provided at the side defined by the first surface 101. The first electrode structure 310 is provided from a conductive material, for example a metal, a metal alloy, a metal compound or heavily doped polycrystalline silicon. A dielectric structure 220 may dielectrically insulate the first electrode structure 310 from further portions of the semiconductor portion 100 outside the impurity zones 110.

In a conductive or forward biased state of the semiconductor device 500, an on-state or forward current flows through the impurity zones 110 in approximately vertical direction between the first and the second surfaces 101, 102.

The impurity zones 110 may be heavily doped anode or cathode zones in the case that the semiconductor device 500 is a semiconductor diode. The impurity zones 110 may be source zones of transistor structures in the case that the semiconductor device 500 is an IGFET or an IGBT. An outer edge of the outermost impurity zone 110 oriented closest to the outer surface 103 may define an outer edge of a cell area 610 where an on-state or forward current predominantly flows in the conductive or forward biased state. The semiconductor portion 100 includes further doped zones and layers forming at least first pn-junctions between each other or/and with the impurity zones 110.

In an edge area 690 surrounding the cell area 610 and directly adjoining the outer surface 103 impurity zones 110, which are connected to the first electrode structure 310 and through which an on-state or forward current flows in the conductive or forward biased state, are absent and not electrically connected to the first electrode structure 310, or disabled for other reasons. Only a negligible portion of an on state or forward current flows in the edge area 690 in the vertical direction.

In a transition area 650 between the cell area 610 and the edge area 690, the on-state or forward current density may decrease between the cell area 610 and the edge area 690. Equipotential lines are approximately parallel to the first and second surfaces 101, 102 in the cell area 610. In semiconductor devices 500 providing a lateral accommodation of the electric field, the equipotential lines predominantly extend along the vertical direction in the edge area 690.

The cell area 610 may include active portions with functional impurity zones 110 and inactive portions without any impurity zones 110 or with non-functional impurity zones 110, e.g. in the vertical projection of connection lines. The connection lines may connect gate electrodes of transistor structures with gate pads or may be connected to sense transistors, temperature sensors or other electric structures within the cell area 610.

At least in the edge area 690 of the semiconductor portion 100, a density of recombination centers 190 is higher than in an active portion of the cell area 610. According to an embodiment, the recombination center density in the edge area 690 exceeds a mean recombination center density in the active portion of the cell area 610 by at least 10 times, for example by at least hundred times. The recombination center density may gradually decrease starting from a high value in the edge area 690 in the direction to the lateral center of the semiconductor portion 100 such that in the cell area 610 the recombination center density is higher in a section close to the edge area 690 than in a central section.

When the first pn junctions in the semiconductor portion 100 are forward biased, charge carriers are injected into further portions of the semiconductor portion 100. Some of the injected charge carriers diffuse into the edge area 690. When the first pn junctions switch from the forward biased state to the reverse biased state, charge carriers previously diffused into the edge area 690 have to be drained off, mainly through the impurity zones 110 closest to the edge area 690 and the corresponding contact structures. Those charge carriers drained off from the edge area 690 add to the charge carriers drained off from the cell area 610 and may significantly increase current densities in an outer portion of the cell area 610 oriented to the edge area 690. The current densities increase with increasing di/dt such that, at a sufficiently high di/dt, the current densities result in locally increased temperatures in the outer portion of the cell area 610.

According to the embodiments, the recombination centers 190 in the edge area 690 increase the recombination rate of electrons and holes in the charge carrier plasma and shorten charge carrier lifetime. The resulting lower charge carrier diffusion length results in fewer holes that have to be drained off by contacts in portions of the cell area 610 close to the edge area 690. As a result, commutation and avalanche ruggedness of the semiconductor device 500 is increased. Since the recombination centers 190, which are also effective as scatter centers in the conductive state, are absent in the cell area 610 that carries the predominant portion of the on-state or forward current, the recombination centers 190 do not or only to a low degree adversely affect the on-state or forward resistance of the semiconductor device 500.

The recombination centers 190 may be crystal lattice vacancies, wherein in the edge area 690 the density of the crystal lattice vacancies is higher than in the cell area 610. The crystal lattice vacancies may be lattice distortions, for example intrinsic lattice distortions or lattice distortions resulting from atoms of an additive element which substitute atoms of the crystal lattice of the semiconductor portion 100 and which may locally change the lattice constant. The crystal lattice vacancies embody widely stationary recombination centers 190 resulting in long-term stability for device parameters depending on the distribution of the recombination centers 190.

According to other embodiments, the crystal lattice vacancies may result from a damage implant using damage particles, for example electrons, protons or atoms of a noble gas, e.g., helium (He), argon (Ar), or krypton (Kr).

Another embodiment may provide the implant of atoms of electrically inert elements, for example oxygen or carbon followed by a heating step. During the heating step, the implanted atoms may form clusters generating a lattice distortion. The crystal lattice vacancies can be provided in the edge area 690 with high selectivity against the cell area 610.

According to a further embodiment, the recombination centers 190 are embodied at least in parts by atoms of a metallic recombination element gettered at the crystal lattice vacancies. In the silicon lattice, the metallic recombination atoms form potential quantum wells and are highly effective recombination centers. The metallic recombination element may be a heavy metal with suitable diffusion properties in the crystal lattice of the semiconductor material. In regards to a silicon single crystal, the metallic recombination element may be, for example, platinum (Pt), palladium (Pd), vanadium (V), iridium (Ir), copper (Cu) or gold (Au). According to an embodiment the metallic recombination element is platinum Pt.

The atoms of the metallic recombination element tend to be gettered at lattice vacancies like lattice distortions generated by damage implants, by clusters of implanted electrical inert atoms or lattice disturbances generated by additive elements substituting the semiconductor atoms in the crystal lattice, for example germanium (Ge) in a silicon crystal. The mainly stationary crystal lattice vacancies 190 getter (adsorb and trap) under certain temperature conditions the highly mobile atoms of the metallic recombination elements such that the diffusion length of holes can be effectively reduced in the edge area 690 without adversely affecting the charge carrier mobility in the cell area 610.

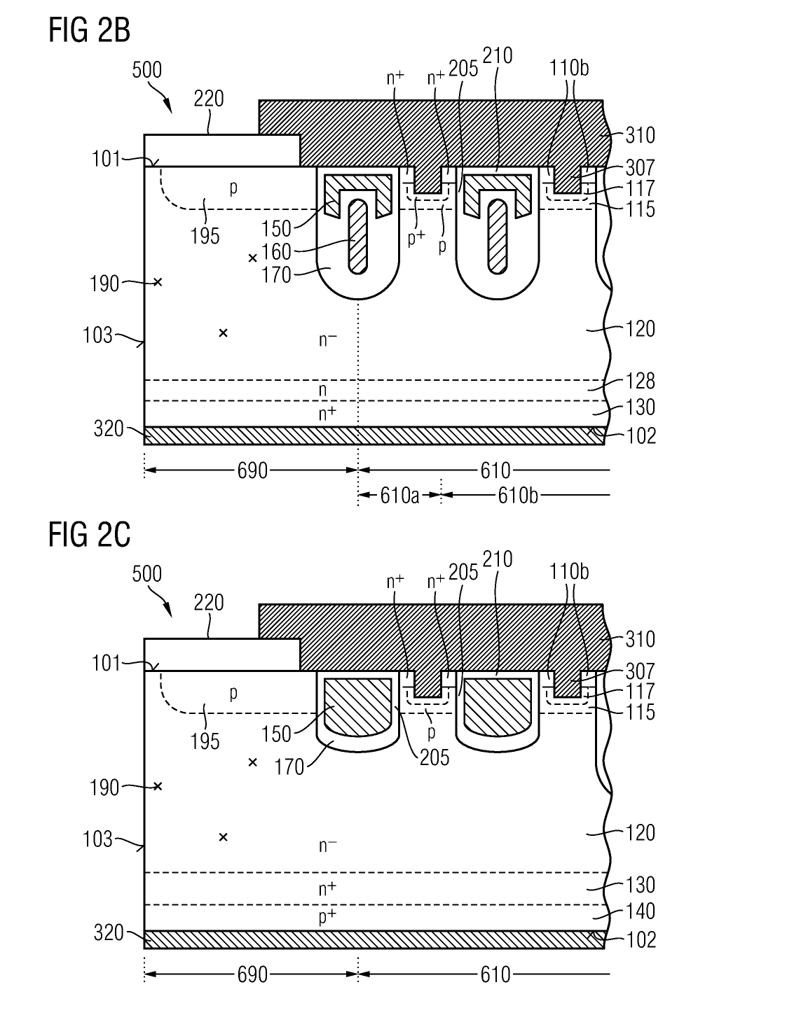

In FIG. 2A the semiconductor device 500 is a semiconductor diode with an anode zone 110a of the second conductivity type along a first surface 101 as an embodiment of the impurity zones 110 of FIG. 1. A first electrode structure 310 is electrically connected to the anode zone 110a, is effective as an anode electrode and forms an ohmic contact with the heavily doped anode zone 110a in the cell area 610. A dielectric structure 220 may dielectrically insulate the first electrode structure 310 from further conductive structures of the semiconductor portion 100 in the edge area 690. Along a second surface 102 parallel to the first surface 101a heavily n-doped impurity layer 130, being effective as cathode layer, may form an ohmic contact with a second electrode structure 320 that is effective as a cathode electrode.

A drift layer 120 of the first conductivity type is formed between the anode zone 110a and the impurity layer 130 and has a mean net impurity concentration lower than the impurity layer 130. The drift layer 120 may include a pedestal layer 128, which directly adjoins the impurity layer 130. The pedestal layer 128 may have an impurity concentration higher than portions of the drift layer 120 outside the pedestal layer and lower than the impurity layer 130 and may be effective as field stop. Thickness and mean net impurity concentration of the drift layer 120 determine on-state resistance and nominal breakdown voltage of the semiconductor device 500. The edge area 690 contains recombination centers 190 at a higher density than the cell area 610. The recombination centers 190 may be crystal lattice vacancies or may include atoms of metallic recombination elements gettered at crystal lattice vacancies. The concentration of recombination centers 190 in the edge area 690 exceeds at least 10 times the concentration of recombination centers in the cell area 610.

FIGS. 2B and 2C show portions of semiconductor devices 500 based on transistor cells. The transistor cells are formed in a cell area 610 of a semiconductor portion 100 with a first surface 101 and a second surface 102 parallel to the first surface 101. Cell trench structures may extend from the first surface 101 into the semiconductor portion 100. The cell trench structures may include gate electrodes 150 and field electrodes 160, which may be formed from heavily doped polycrystalline silicon, respectively. The field electrodes 160 may extend deeper into the semiconductor portion 110 than the gate electrodes 150. The gate electrodes 150 may be electrically coupled to a gate terminal of the semiconductor device 500 or to an output terminal of a gate driver circuit integrated in the semiconductor device 500. A gate dielectric 205 dielectrically couples the gate electrodes 150 with body zones 115 of the second conductivity type. The field electrodes 160 may be without electric connection to other elements of the semiconductor device 500 and may float. According to other embodiments, the field electrodes 160 may be electrically coupled to a source electrode, to a gate electrode, to an output terminal of a driver circuit integrated in the semiconductor device 500 or to an input terminal of the semiconductor device 500.

Trench insulator structures 170 insulate the field electrodes 160 from the semiconductor portion 100 and the gate electrodes 150. The trench insulator structures 170 may be provided from silicon oxide which may be thermally grown or deposited, for example using TEOS (tetraethylorthosilane) as precursor material, silicate glass, silicon nitride, silicon oxynitride or any combination thereof, by way of example. The gate dielectric 205 may be thermally grown semiconductor oxide or a deposited dielectric material, for example a semiconductor oxide, e.g., silicon oxide. A further dielectric structure 210 may dielectrically insulate the gate electrodes 150 from the first electrode structure 310.

The body zones 115 may extend between the cell trench structures, wherein edges of the body zones 115 may be approximately adjusted to the edges of the gate electrodes 150. Between the first electrodes 310 and the body zones 115 source zones 110b of the first conductivity type are formed in the semiconductor portion 100. Heavily doped contact zones 117 may form ohmic contacts between the first electrode structure 310 and the body zones 115. Contact structures 307 may be between neighboring source zones 110b.

Source zones 110b through which, in a conductive state of the semiconductor device 500, an on-state current flows are exclusively provided within the cell area 610 and are absent in the edge area 690. The source zones 110b embody impurity zones 110 in the sense of FIG. 1.

A drift layer 120 of the first conductivity type separates the body zones 115 from a heavily doped impurity layer 130 of the first conductivity type. In the edge area 690, a junction termination extension 195 of the second conductivity type may extend from the first surface 101 into the semiconductor portion 100. The drift layer 120 may include a pedestal layer 128, which directly adjoins the impurity layer 130. The pedestal layer 128 may have an impurity concentration higher than portions of the drift layer 120 outside the pedestal layer and lower than the impurity layer 130 and may be effective as field stop.

In the edge area 690 surrounding the cell area 610 and directly adjoining an outer surface 103 connecting the first and the second surfaces 101, 102, a density of recombination centers 190 embodied as crystal lattice vacancies with or without gettered atoms of metallic recombination elements is higher than at least in active portions of the cell area 610. A distribution of the recombination centers 190 along a vertical direction perpendicular to the first and second surfaces 101, 102 may be approximately uniform, may decrease or increase with increasing distance to the first surface 101 or may have a maximum at a distance to both first and second surfaces 101, 102.

According to the illustrated embodiment, the cell area 610 includes a first portion 610a directly adjoining the edge area 690 and a second portion 610b in a distance to the edge area 690 and the densities of recombination centers 190 in the edge area 690 and the first portion 610a of the cell area 610 are higher than in the second portion 610b.

The semiconductor device 500 of FIG. 2B is an IGFET with the impurity layer 130 electrically connected to the second electrode structure 320.

The semiconductor device 500 of FIG. 2C is an IGBT with a heavily doped collector layer 140 of the second conductivity type between the impurity layer 130 and the second electrode structure 320. The cell trench structures may include gate electrodes 150 and may be provided without field electrodes 160.

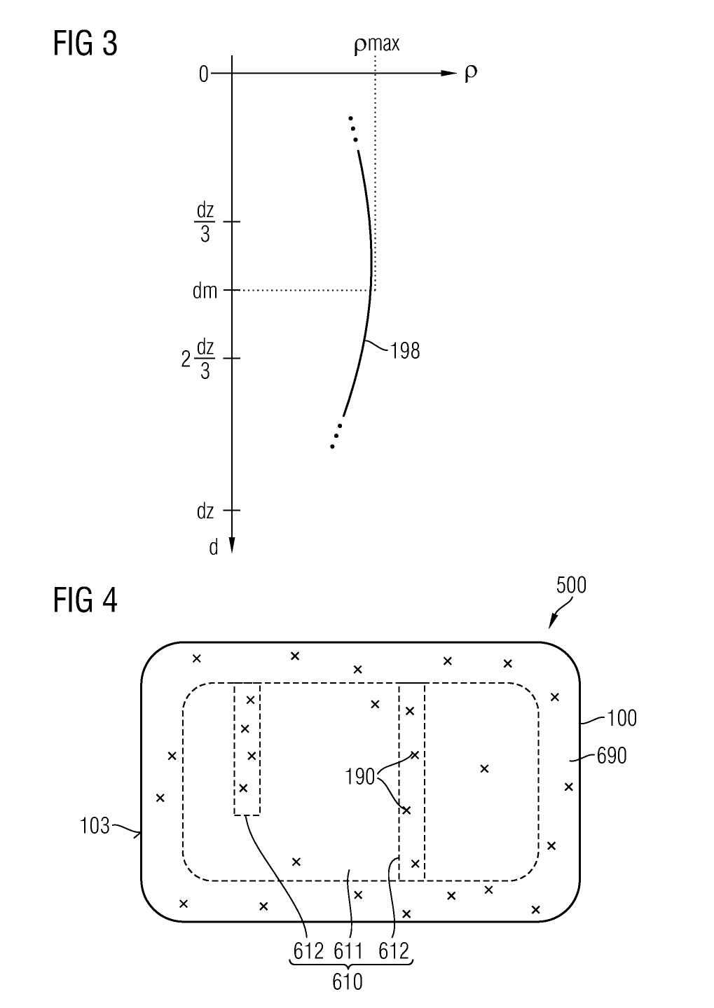

According to the embodiment illustrated in FIG. 3, a recombination center density ρ has a local maximum ρmax in a first distance dm to the first and second surfaces. The recombination center density ρ may have further local maxima along interfaces with non-semiconducting layers, e.g., oxide layers and metal electrodes as well as along pn junctions. The first distance may be fall in the medium third of the vertical extension of a semiconductor portion having a thickness dz. The vertical density distribution (profile) 198 of the recombination centers 190 may be adjusted by the implantation depth of electric inert atoms like oxygen and carbon, by way of example. Other embodiments may provide an epitaxial growth of at least a section of the semiconductor portion 100, wherein when the epitaxy process reaches a thickness corresponding to the first distance dm in the finalized device, measures may be taken for locally increasing the density of crystal lattice vacancies, e.g., a masked growth of a silicon germanium crystal on a silicon underlayer, masked damage implants or other methods locally damaging the crystal lattice. The crystal defects may later be decorated with gettered atoms of a metallic recombination element.

The semiconductor device 500 of FIG. 4 includes a cell area 610 with an active portion 611 having a low density of recombination centers 190 and inactive portions 612 having a high density of recombination centers 190. The inactive portions 612a, 612b may be fractions of the cell area 610 without functional transistor cells, e.g., in the vertical projection of connection lines to sense cells, field electrodes or gate electrodes, by way of example. The inactive portions 612 may be stripe-shaped and may extend from the edge area 690 into the cell area 610, wherein the inactive portions 612 may cross the cell area 610 or end within the cell area 610. The recombination center densities in the inactive portions 612 and in an edge area 690 surrounding the cell area 610 may be approximately equal.

FIG. 5 shows a semiconductor device 500 with a semiconductor portion 100 containing one or more contact zones 111 having the same conductivity type. A first electrode structure 310 is electrically connected to the one or more contact zones 110. For example, the contact zones 111 may be formed directly adjoining a first surface 101 of the semiconductor portion 100 and the first electrode structure 310 may directly adjoin the first surface 101. According to other embodiments, a dielectric structure 220 may be provided between the first electrode structure 310 and the semiconductor portion 100 and contact structures 307 may extend between the first electrode structure 310 and the contact zones 111 through openings of the dielectric structure 220. The contact structures 307 may directly adjoin the first surface 101 or may extend into the semiconductor portion 100, wherein the contact zones 111 are formed along a buried edge of the contact structures 307.

At least in a fraction of the semiconductor portion 100 a density of crystal lattice vacancies exceeds 10¹³ cm⁻³, e.g., at least 5×10¹³ cm⁻³ or at least 10¹⁴ cm⁻³, which is significantly higher than the typical density of crystal lattice vacancies in a semiconductor wafer specified for the manufacture of high voltage power semiconductor devices, for example HV-MOSFETs (high voltage metal oxide semiconductor field effect transistors). The crystal lattice vacancies may result from a specific heat treatment, for example an RTP (rapid thermal process) in a nitrogen atmosphere or a high-temperature oxidation step using hydrochloric acid (HCl) added to a gaseous atmosphere.

In addition, the semiconductor portion 100 contains atoms of a metallic recombination element 191. Metallic recombination elements provide quantum mechanical states in the band gap of the semiconductor material of the semiconductor portion 100. The atoms of the metallic recombination element 191 are highly effective recombination centers for holes and electrons in the respective semiconductor material, e.g., in a silicon crystal. The metallic recombination element may be a heavy metal with suitable diffusion properties in the respective semiconductor crystal. By way of example, the metallic recombination elements include platinum (Pt), palladium (Pd), vanadium (V), iridium (Ir) and gold (Au) and the semiconductor material may be silicon.

At least some of the atoms of the metallic recombination element 191 may be gettered (adsorbed and trapped) at some of the stationary crystal lattice vacancies. As a result, the presence of the crystal lattice vacancies leads to a higher amount of atoms of the metallic recombination elements 191 in the semiconductor material of the semiconductor portion 100 at shorter diffusion times. The thermal budget required for diffusing the atoms of the metallic recombination elements 191 out of a source containing the atoms can be reduced such that the overall temperature budget applied to the contact zones 111 can be significantly reduced. As a result, the contours of the contact zones 111 remain well defined with steep impurity concentration gradients such that a shift of a threshold voltage and a degradation of single-pulse avalanche capability can be avoided. A high impurity concentration in the contact zones 111 also ensures that the semiconductor device 500 is less prone to latch-up events.

According to an embodiment, the density of crystal lattice vacancies is higher in an edge area than in at least portions of a cell area surrounded by the edge area. As a consequence, the density of atoms of one or more metallic recombination elements is higher in the edge area than in the cell area. The metallic recombination atoms reduce the diffusion length locally such that the number of charge carriers that must be drained off in the commutation case can be significantly reduced by increased carrier recombination.

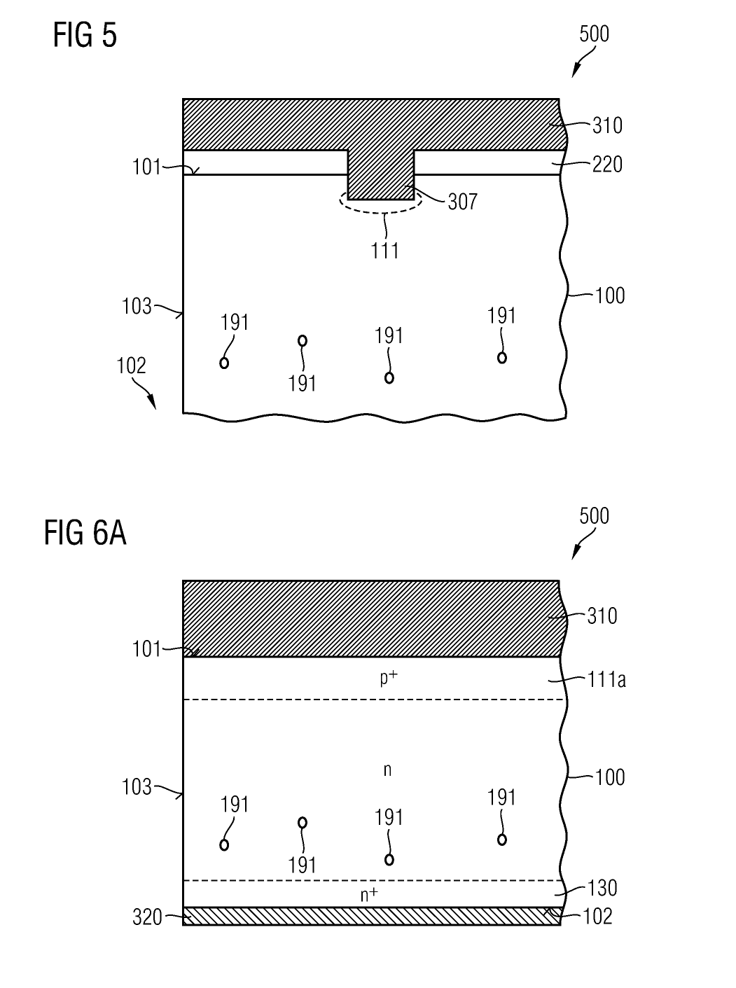

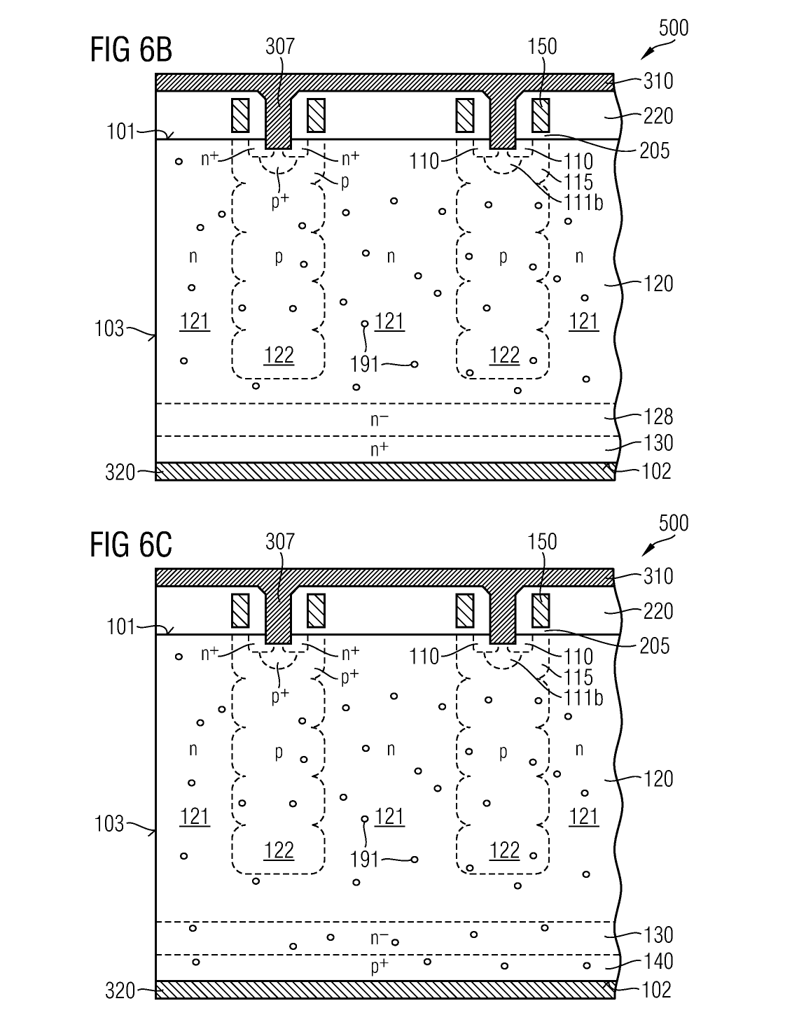

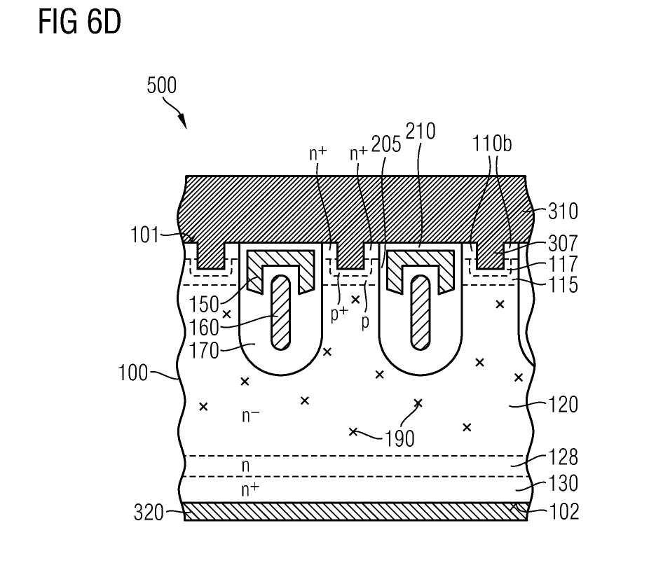

According to FIG. 6A, the semiconductor device 500 is a semiconductor diode with one single anode zone 111a forming a contact zone 111 in the sense of FIG. 5. The anode zone 111a in the semiconductor portion 100 may directly adjoin the first surface 101. A first electrode structure 310 directly adjoins the anode zone 111a and forms an anode electrode. A heavily doped impurity layer 130 of the first conductivity type directly adjoins a second surface 102 parallel to the first surface 101 and provides a cathode zone. A second electrode structure 320 electrically connected to the impurity layer 130 provides a cathode electrode. A drift zone 120 of the first conductivity type separates the anode zone 111a and the impurity layer 130.

The semiconductor portion 100 includes crystal lattice vacancies decorated with atoms of one or more metallic recombination elements 191, for example platinum (Pt), which reduces the charge plasma injected through the forward biased pn junction between the anode zone 111a and the drift layer 120 in the forward mode.

FIG. 6B refers to a super junction IGFET with a super junction structure comprising first columns 121 of the first conductivity type and second columns 122 of the second conductivity type alternately arranged in a drift zone 120 of a semiconductor portion 100. The first and second columns 121, 122 may be stripe-shaped with a first lateral extension in the cross-sectional plane significantly falling below a second lateral extension perpendicular to the cross-sectional plane. According to other embodiments, at least the first or the second columns 121, 122 may have a rectangular, e.g., quadratic lateral cross-sectional area with or without rounded corners, or an approximately circular cross-sectional area.

The second columns 122 may be connected with body zones 115 of the same conductivity type which are formed in the vertical projection of the second columns 122 between a first surface 101 of the semiconductor portion 100 and the second columns 122. The body zones 115 separate the first columns 121 from source zones 110 of the first conductivity type. Gate dielectrics 205 dielectrically couple the body zones 115 with gate electrodes 150 which may be outside the semiconductor portion 100. Heavily doped contact zones 111b of the second conductivity type provide ohmic contacts between contact structures 307 to a first electrode structure 310 and the body zones 115.

A pedestal layer 128, which may have a higher or lower impurity concentration than the first columns 121, may be provided between the second columns 122 and an impurity layer 130 that directly adjoins a second electrode structure 320 along a second surface 102 parallel to the first surface 101. Atoms of one or more metallic recombination elements 191 are gettered at crystal lattice vacancies in the semiconductor portion 100. The density of atoms of the metallic recombination elements 191 is at least 10¹³ cm⁻³, e.g., at least 5×10¹³ cm⁻³ or at least 10¹⁴ cm⁻³. Since a comparatively low thermal budget suffices to diffuse the atoms of the metallic recombination elements 191 to the stationary crystal lattice vacancies, the vertical and lateral impurity profiles of the contact zones 111b can be kept steep.

The semiconductor device 500 of FIG. 6C is an IGBT with a collector layer 140 of the second conductivity type between the impurity layer 130 and the second electrode structure 320. The collector layer 140 may be a contiguous layer or may include islands of the first conductivity type.

FIG. 6D shows a semiconductor portion 100 with a first surface 101 and second surface 102 parallel to the first surface 101. Cell trench structures extend from the first surface 101 into the semiconductor portion 100. The cell trench structures may include gate electrodes 150 and field electrodes 160, wherein the field electrodes 160 may extend deeper into the semiconductor portion 110 than the gate electrodes 150. The cell trench structures may be wider than semiconductor mesas formed between neighboring cell trench structures.

A gate dielectric 205 dielectrically couples the gate electrodes 150 with body zones 115 of the second conductivity type. The field electrodes 160 may be without electric connection to other elements of the semiconductor device 500 and may float. According to other embodiments, the field electrodes 160 may be electrically coupled to a source electrode, to a gate electrode, to an output terminal of a driver circuit integrated in the semiconductor device 500 or to an input terminal of the semiconductor device 500.

Trench insulator structures 170 insulate the field electrodes 160 from the semiconductor portion 100 and the gate electrodes 150. The trench insulator structures 170 may be provided from silicon oxide which may be thermally grown or deposited, for example using TEOS as precursor material, silicate glass, silicon nitride, silicon oxynitride or any combination thereof, by way of example. The gate dielectric 205 may be a thermally grown semiconductor oxide or a deposited dielectric material, for example silicon oxide. A further dielectric structure 210 may dielectrically insulate the gate electrodes 150 from the first electrode structure 310.

The body zones 115 may extend between the cell trench structures, wherein edges of the body zones 115 may be approximately adjusted to the edges of the gate electrodes 150. Between the first electrodes 310 and the body zones 115, source zones 110b of the first conductivity type are formed in the semiconductor portion 100. Heavily doped contact zones 117 may form ohmic contacts between the first electrode structure 310 and the body zones 115. Contact structures 307 may be between neighboring source zones 110b. The source zones 110b through which in a conductive state of the semiconductor device 500 an on-state current flows are exclusively provided within a cell area 610 and are absent in an edge area 690.

A drift layer 120 of the first conductivity type separates the body zones 115 from a heavily doped impurity layer 130 of the first conductivity type. In the edge area 690, a junction termination extension 195 of the second conductivity type may extend from the first surface 101 into the semiconductor portion 100. The drift layer 120 may include a pedestal layer 128, which directly adjoins the impurity layer 130. The pedestal layer 128 may have an impurity concentration higher than portions of the drift layer 120 outside the pedestal layer and lower than the impurity layer 130 and may be effective as field stop.

The semiconductor portion 100 contains crystal lattice vacancies and atoms of a metallic recombination element at last partly gettered at some of the crystal lattice vacancies, wherein at least in a fraction of the semiconductor portion a density of the crystal lattice vacancies exceeds 10¹³ cm⁻³. According to an embodiment the relevant density of crystal lattice vacancies is at least 5×10¹³ cm⁻³, e.g., at least 10¹⁴ cm⁻³ and may reach values in a range from 10¹⁸ cm⁻³ to 10¹⁹ cm⁻³.

A distribution of the recombination centers 190 along a vertical direction perpendicular to the first and second surfaces 101, 102 may be approximately uniform, may decrease or increase with increasing distance to the first surface 101 or may have a maximum at a distance to both first and second surfaces 101, 102.

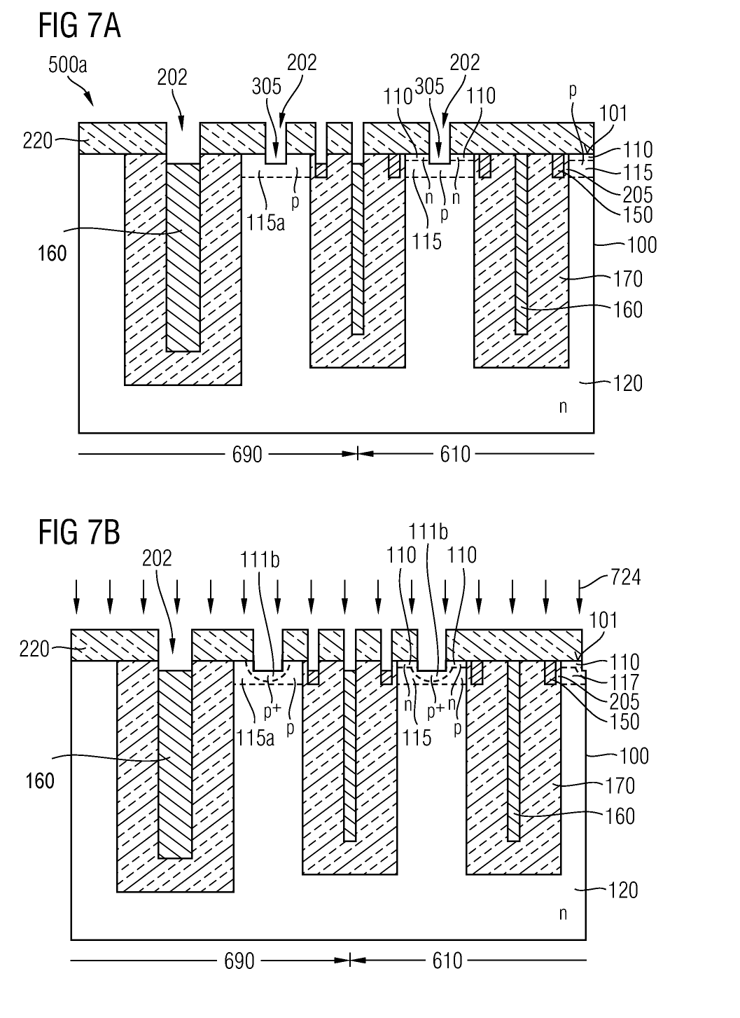

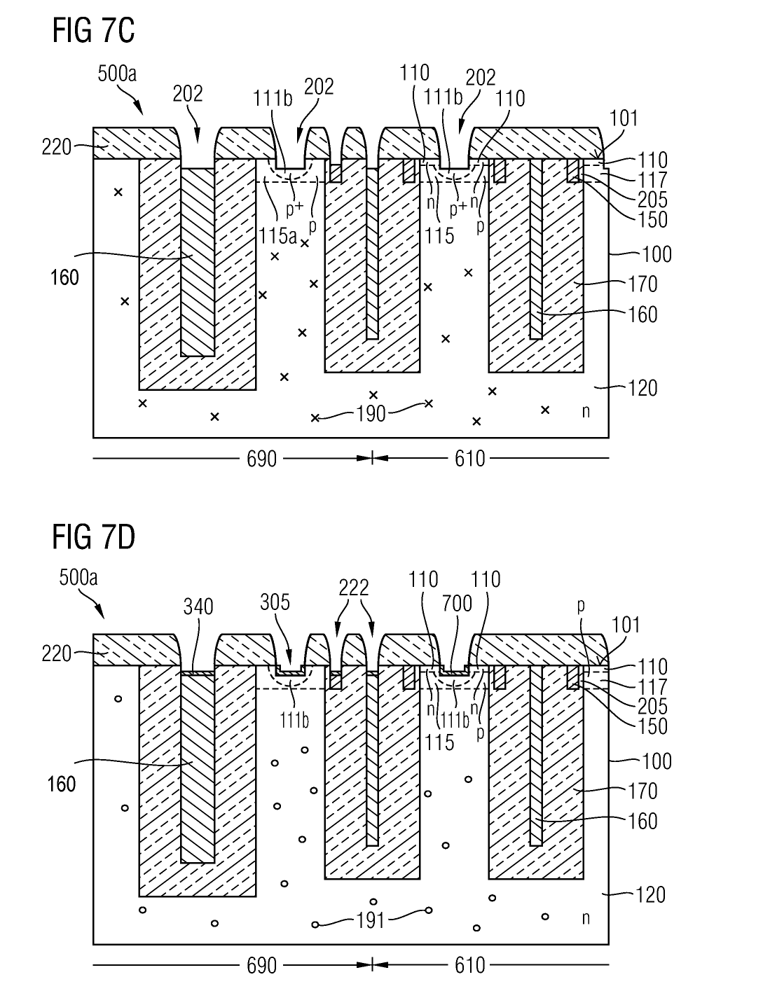

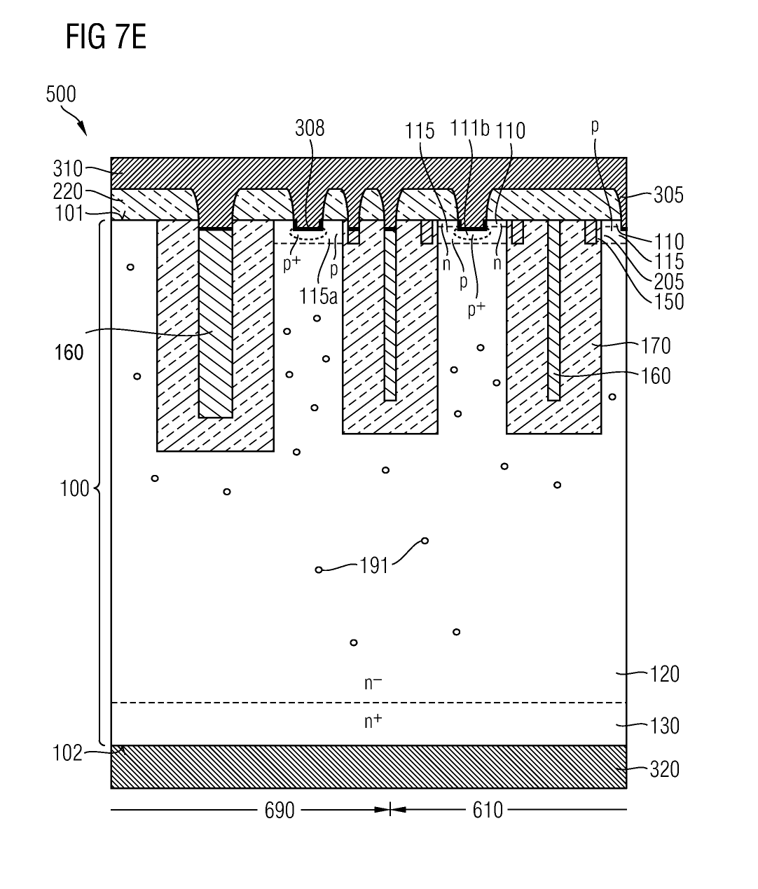

FIGS. 7A to 7D refer to a method of manufacturing a semiconductor device using an RTP (rapid thermal process) provided in context of an implant for generating crystal lattice vacancies in a silicon lattice. FIG. 7A shows a portion of one of a plurality of semiconductor dies 500a formed in a semiconductor substrate. The semiconductor substrate is a wafer, for example a single crystalline silicon wafer. Outside the illustrated portion, the semiconductor die 500a may include further doped and undoped sections, epitaxial semiconductor layers and previously fabricated insulating structures. The semiconductor die 500a includes a drift layer 120 of a first conductivity type in both a cell area 610 and an edge area 690 surrounding the cell area 610. Cell trench structures are provided in the semiconductor portion 100, wherein the cell trench structures formed in the edge area 690 may be wider and may extend deeper into the drift layer 120 than the cell trench structures in the cell area 610. The cell trench structures may have approximately vertical sidewalls and may be evenly spaced at a pitch of some micrometers. The cell trench structures may be wider than mesa portions of the semiconductor portion 100 between the cell trench structures. The cell trench structures include field electrodes 160 and gate electrodes 150. An insulation structure 170 dielectrically insulates the field electrodes 160 from the gate electrodes 150 and the drift layer 120. A gate dielectric 205 may separate the gate electrodes 150 from body zones 115, 115a of the second conductivity type. The body zones 115, 115a may extend between neighboring cell trench structures. A buried edge of the body zones 115, 115a distant from a first surface 101 of the semiconductor portion may be aligned with a buried edge of the gate electrodes 150. Source wells may be formed between the first surface 101 and the body zones 115 of the cell area 610. Source wells are absent in the edge area 690.

A dielectric layer 220 formed from one or more dielectric material(s) is provided on the first surface 101 and patterned by photolithographic means such that openings 202 in the dielectric layer 220 expose at least central portions of source wells in the cell area 610. The central portions may have approximately equal distances to both neighboring cell trench structures. In the edge area 690, one or more of the body zones 115a or field electrodes 160 may be exposed. Using the patterned dielectric layer 220 as an etch mask, contact grooves 305 may be etched through the source wells into the semiconductor portion 100.

FIG. 7A shows the contact grooves 305, which may reach or extend into the body zones 115 and 115a. In the cell area 610, from each source well two source zones 110 may be formed on opposing sides of the contact groove 305. Impurities of the second conductivity type 724 may be introduced through the openings 202 of the dielectric layer 220.

FIG. 7B shows the contact zones 111b formed from the introduced impurities. The contact zones 111b have a higher impurity concentration than the body zones 115. For example, the mean net impurity concentration in the contact zones 111b may be at least ten times higher than the net impurity concentration in the body zones 115. According to an embodiment, the maximum impurity concentration in the contact zones 115 may be greater than 10¹⁹ cm⁻³. The body contact zones 111b provide a low-ohmic contact to the body zones 115 and reduce the risk of latch-up effects.

For activating the implanted impurities, a temper step anneals the damages in the crystal lattice of the semiconductor material and integrates the impurity atoms in the crystal lattice. According to an embodiment, the anneal for the implant is provided by an RTP in a nitrogen atmosphere which results in the formation of crystal lattice vacancies in the silicon lattice.

FIG. 7C shows the generated crystal lattice vacancies 190 in the semiconductor portion 100. The density of the crystal lattice vacancies exceeds at least 10¹³ cm⁻³. According to an embodiment, the relevant density of crystal lattice vacancies is at least 5×10¹³ cm⁻³, e.g., at least 10¹⁴ cm⁻³ and may reach values in a range from 10¹⁸ cm⁻³ to 10¹⁹ cm⁻³.

Atoms of a metallic recombination element are introduced into the semiconductor portion 100. At this stage, no significant thermal budget has been applied to the semiconductor substrate 500a such that the crystal lattice vacancies 190 are not annealed and still present in the semiconductor portion 100. For example, an impurity source is brought into contact with the exposed sections of the semiconductor portion 100, wherein the impurity source contains atoms of the metallic recombination element, for example platinum (Pt), palladium (Pd), vanadium (V), iridium (Ir) or gold (Au).

In accordance with other embodiments, the atoms or ions of the respective metallic recombination elements may be implanted through the openings of the dielectric layer 220 into the semiconductor portion 100. Another embodiment may provide depositing one or more layers containing the metallic recombination element(s). The deposited layers may be tempered such that the material of the deposited layer reacts with the silicon material of the semiconductor die 550a and forms a metal semiconductor compound, for example PtSi. According to another embodiment, layered platinum silicide structures 700 are formed on exposed surfaces of the semiconductor dies 500a through tempering a deposited layer consisting of or containing platinum (Pt) at a temperature between 450 and 500° C.

Then the semiconductor die 500a may be tempered at a temperature of at least 750° C. such that platinum atoms or ions diffuse from the platinum silicide structure 700 into the semiconductor portion 100.

As shown in FIG. 7D at least some of the platinum atoms or ions are gettered at the crystal lattice vacancies 190. The gettered atoms 191 of platinum or another the metallic recombination element are stationary, may distribute evenly in the semiconductor material of the semiconductor portion 100 and are highly effective recombination centers reducing charge carrier lifetime and improving avalanche and commutation ruggedness. The layers containing atoms of a metallic recombination element may be removed or replaced by other metallic contact layers.

FIG. 7E shows a portion of a semiconductor device 500 resulting from the above described method with metal silicide layers 308 formed between the first electrode structure 310 and the source and contact zones 110, 111b. The method modifies an RTP provided for activating a previous implant in order to increase the density of crystal lattice vacancies which are used to getter atoms 191 of a metallic recombination element.

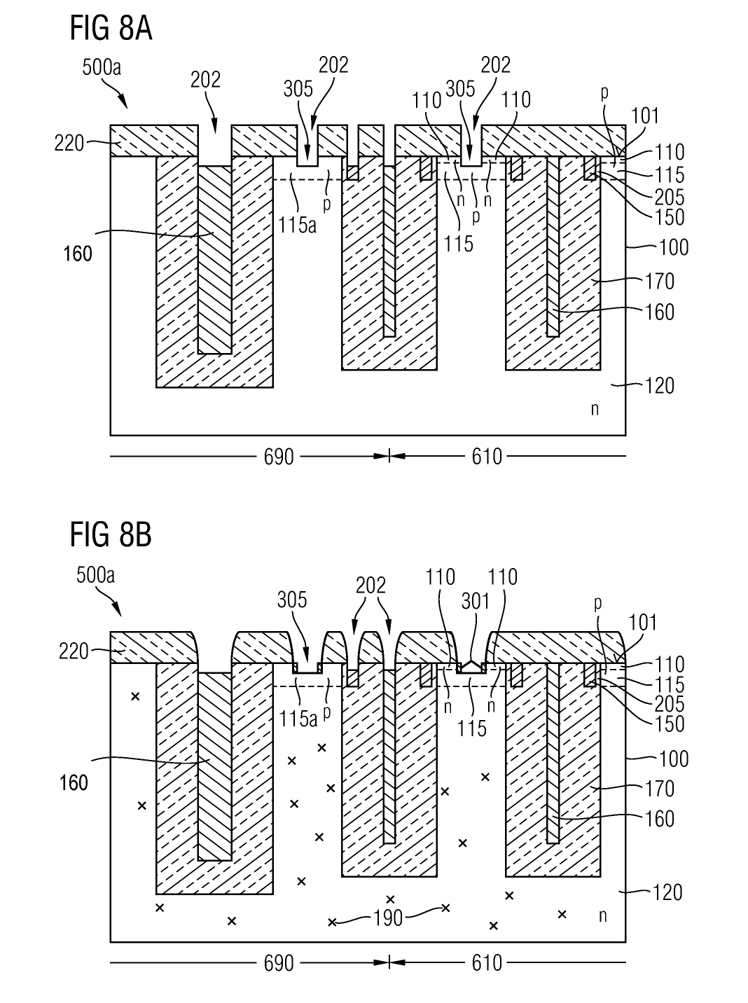

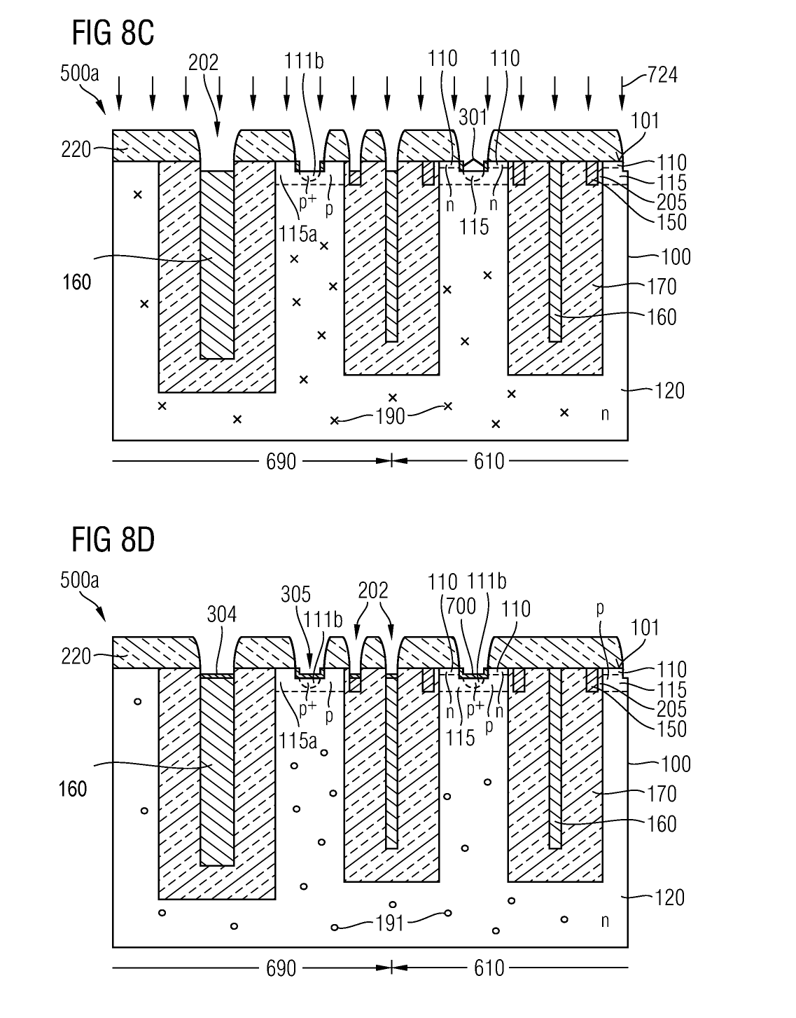

FIGS. 8A to 8D depict the crystal lattice vacancies before the implant used for forming the contact zones 111b. In regards to FIG. 8A, reference is made to the description of FIG. 7A.

After forming the contact grooves 305, a high temperature process is performed in a gaseous atmosphere containing hydrochloric acid (HCl) to form crystal lattice vacancies 190. The high temperature process may be performed in an inert gaseous atmosphere containing the hydrochloric acid (HCl). According to the illustrated embodiment the high temperature process is an oxidation process forming an oxide layer on exposed portions of the contact grooves 305. The oxide layer may be removed in the following. According to an embodiment an impurity mask 301 may be formed from the grown oxide layer by a spacer etch, for example by RIE (reactive ion beam etching).

FIG. 8B shows the impurity mask 301 covering sidewalls of the contact grooves 305 and exposing the bottoms of the contact grooves 305. As a consequence of the high temperature process in presence of hydrochloric acid (HCl), crystal lattice vacancies 190 are formed in the semiconductor portion 100.

Impurities 724 of the second conductivity type are introduced, for example implanted into the semiconductor portion 100 through the exposed bottoms of the contact grooves 305 using the dielectric layer 220 and the impurity mask 301 as combined impurity mask, wherein the impurity mask 301 avoids a counter doping of the source zones 110.

FIG. 8C shows the resulting contact zones 111b. At this stage, no significant thermal budget has been applied to the semiconductor substrate 500a such that the crystal lattice vacancies 190 are not annealed and still present in the semiconductor portion 100. The impurity mask 301 may be removed and atoms of a metallic recombination element are diffused into the semiconductor portion 100, for example by forming a platinum silicide layer 700 on exposed portions of the contact grooves 305 and tempering the platinum silicide layer at the diffusion temperature of platinum. The crystal lattice vacancies 190 of FIG. 8C trap some of the platinum atoms.

FIG. 8D shows the platinum silicide layer 700 and the atoms 191 of the metallic recombination element gettered at the crystal lattice vacancies.

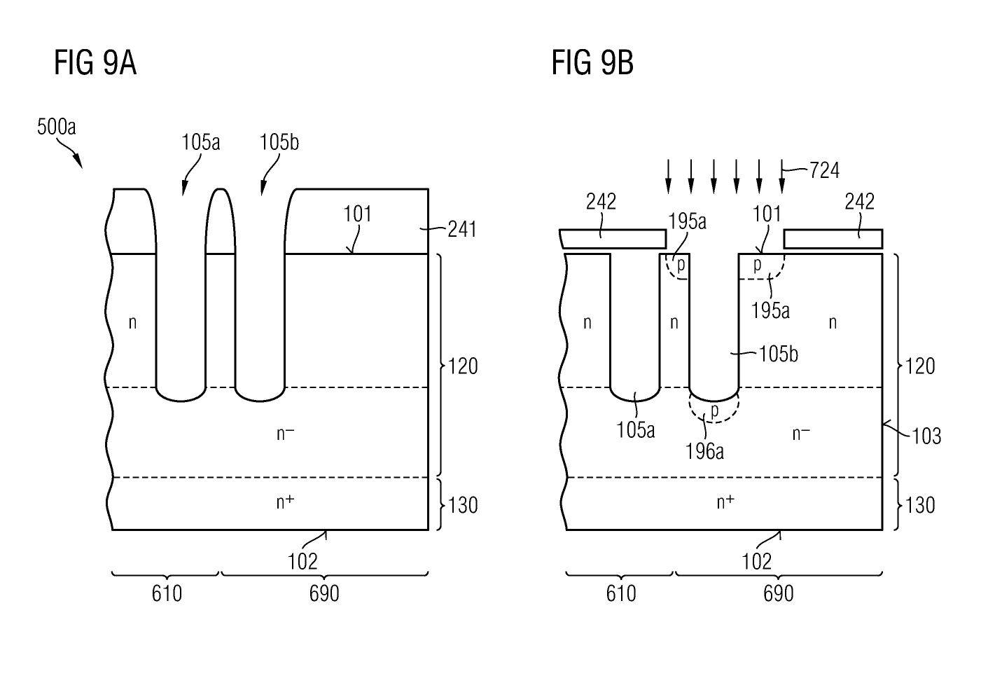

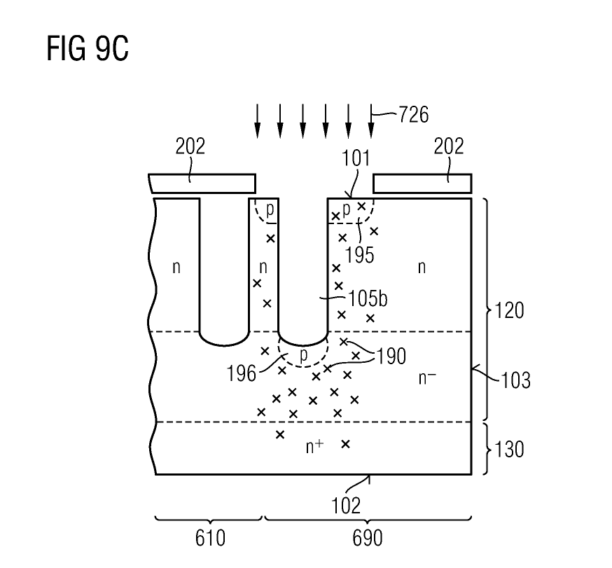

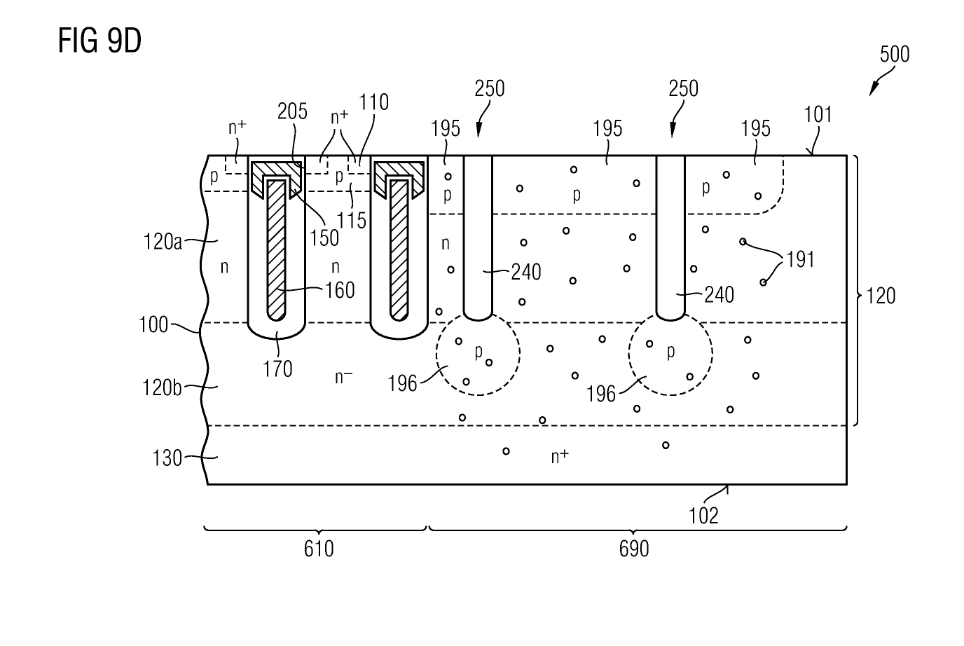

FIGS. 9A to 9D refer to a method providing a locally increased number of recombination centers. Using an etch mask 241 gate and termination trenches 105a, 105b are etched from a first surface 100 into a semiconductor substrate 500a, for example a single crystalline silicon wafer with a heavily doped impurity layer 130 of the first conductivity type along a second surface 102 parallel to the first surface 101 and a lower doped drift layer 120 of the first conductivity type between the first surface 101 and the impurity layer 130.

FIG. 9A shows a cell trench 105a in a cell area 610 of a semiconductor die and a termination trench 105b in an edge area 690 surrounding the cell area 610. The drift layer 120 may include a lower doped portion adjoining the impurity layer 130 and a more heavily doped portion between the first surface 101 and the lower doped portion. The gate and termination trenches 105a, 105b end in the drift layer 120. In the cell area 610 the cell trenches 105a may be wider than mesa portions of the semiconductor portion 100 between the cell trenches 105a.

An auxiliary mask 242 is provided on the first surface 101. The auxiliary mask 242 may be diaphragm/face plate disposed on the first surface 101 and covers at least an active portion of the cell area 610 and an outer portion of the edge area 690 directly adjoining a kerf area along which the semiconductor dies of the semiconductor substrate 500a are separated in the course of a singularization process. The auxiliary mask 242 exposes an inner portion of the edge area 690 adjoining the cell area 610 and including the one or more termination trenches 105b and portions of the respective semiconductor die directly adjoining the termination trenches 105b. Using the auxiliary mask 242 as an implant mask, impurities 724 of the second conductivity type are implanted into the semiconductor substrate 500a through the bottom of the termination trenches 105 and exposed sections of the first surface 101.

FIG. 9B shows first implant zones 195a along the first surface 101 in portions of the edge area 690 exposed by the auxiliary mask 242 and a second implant zone 196a at the bottom of the termination trench 105b.

Using the auxiliary mask 242 a second time, a damage implant is performed, e.g., a high energy implant, atoms of a noble gas, or atoms of electrical inert elements like oxygen or carbon. An embodiment provides the implant of argon (Ar) atoms at a high implant dose.

FIG. 9C shows the generated stable and stationary defect clusters of crystal lattice vacancies 190 generated by the implant of argon (Ar) atoms at a high implant dose. Atoms of a metallic recombination element, e.g., platinum, may be diffused into the semiconductor substrate 500a using, for example, one of the above described methods.

FIG. 9D refers to the semiconductor portion 100 of a finalized semiconductor device 500 with atoms of one or more metallic recombination elements 191 gettered at the crystal lattice vacancies 190 of FIG. 9C. The applied thermal budget forms lateral termination extensions 195 from the first implant zones 195a of FIG. 9B and field shaping zones 196 from the second implant zones 196a of FIG. 9B. The termination trenches 105b of FIG. 9B may be filled with a dielectric material to form termination trenches 240. In regards to the transistor cells in the cell area 610 reference is made to the description of the previous figures.

The method provides enhanced commutation ruggedness without adversely affecting the on state characteristics of the concerned semiconductor devices at comparatively low process complexity and without further mask processing. Since only a low thermal budget is required and applied after formation of contact zones, the impurity concentration in the contact zones remains high and provides a low contact resistance to the body zones such that high avalanche ruggedness may be preserved.

A method of manufacturing a semiconductor device includes providing an auxiliary mask that covers at least a portion of a cell area and that exposes at least a portion of an edge area of a semiconductor die comprised in a semiconductor substrate, wherein the edge area surrounds the cell area. The method further includes generating recombination centers in portions of the semiconductor substrate exposed by the auxiliary mask.

Generating the recombination centers may comprise introducing atoms of a metallic recombination element to provide metallic recombination centers in the portions exposed by the auxiliary mask. Before providing the auxiliary mask contact grooves may be introduced into the semiconductor die. The atoms of the metallic recombination element may be introduced into the semiconductor die through the contact grooves. After introducing the atoms of the metallic recombination element, contact structures may be provided in the contact grooves.

Crystal lattice vacancies may be generated in portions of the semiconductor die exposed by the auxiliary mask to generate non-metallic recombination centers. The atoms of the metallic recombination element may be introduced into the semiconductor die after generating the crystal lattice vacancies. Generating the crystal lattice vacancies may comprise implanting damage particles into exposed portions of the semiconductor die using the auxiliary mask as an impurity mask. Alternatively or in addition, generating the crystal lattice vacancies may comprise implanting atoms of electrically inert elements into the exposed portions of the semiconductor die using the auxiliary mask as an impurity mask. In addition or alternatively, generating the crystal lattice vacancies may comprise locally varying a lattice constant in a semiconductor substrate by introducing an additive element whose atoms are adapted to be incorporated at lattice positions of the semiconductor substrate.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

1. A semiconductor device comprising:
a semiconductor portion that comprises one or more impurity zones of the same conductivity type and
a first electrode structure electrically connected to the one or more impurity zones in a cell area of the semiconductor portion, wherein
the cell area comprises impurity zones that extend from a first surface into the semiconductor portion, the impurity zones configured to convey an on-state or forward current in a conductive or forward biased state of the semiconductor device, the semiconductor device further comprising: an edge area surrounding the cell area and, directly adjoining an outer surface of the semiconductor portion and devoid of the impurity zones, wherein in the edge area a density of crystal lattice vacancies is higher than in the cell area and a density of atoms of metallic recombination elements is higher than in the cell area, and wherein some of the atoms of the metallic recombination elements are gettered at some of the crystal lattice vacancies such that a recombination center density is higher in the edge area than in an active portion of the cell area.

2. The semiconductor device according to claim 1, wherein
the impurity zones correspond to source zones of a first conductivity type and the semiconductor portion further comprises a drift zone of the first conductivity type and body zones of a complementary second conductivity type, the body zones separating the source zones from the drift zone in the cell area.

3. The semiconductor device according to claim 1, wherein
in the edge area a density of crystal lattice vacancies is higher than in the cell area.

4. The semiconductor device according to claim 1, wherein
in the edge area a density of atoms of metallic recombination elements is higher than in the cell area.

5. (canceled)

6. The semiconductor device according to claim 1, wherein
the recombination center density in the edge area of the semiconductor portion exceeds at least ten times a recombination center density in the cell area.

7. The semiconductor device according to claim 1, wherein
in the edge area a density of damage particles is higher than in the cell area.

8. The semiconductor device according to claim 1, wherein
in the edge area a density of atoms of electric inert elements selected from a group that comprises oxygen and carbon is higher than in the cell area.

9. The semiconductor device according to claim 1, wherein
in the edge area a density of lattice distortions resulting from varying lattice constants is higher than in the cell area.

10. The semiconductor device according to claim 1, wherein
in the edge area a density of atoms of an additive element adapted to substitute atoms of a crystal lattice of the semiconductor portion is higher than in the cell area.

11. The semiconductor device according to claim 1, wherein
a profile of the recombination center density along a vertical direction perpendicular to a first surface of the semiconductor portion oriented to the first electrode structure has a maximum in a middle third of a distance between the first surface and a second surface parallel to the first surface.

12. A semiconductor device comprising:
a semiconductor portion that contains crystal lattice vacancies and atoms of a metallic recombination element at last partly gettered at some of the crystal lattice vacancies, wherein at least in a fraction of the semiconductor portion a density of the crystal lattice vacancies exceeds 1013 cm-3.

13. The semiconductor device according to claim 12, comprising:
one or more contact zones of a same conductivity type in the semiconductor portion, wherein
a first electrode structure is electrically connected to the one or more contact zones in a cell area, and
a density of crystal lattice vacancies in an edge area surrounding the cell area is higher than in the cell area.

14. A method of manufacturing a semiconductor device, comprising:
generating crystal lattice vacancies in at least portions of a semiconductor substrate, wherein a density of the crystal lattice vacancies exceeds 1013 cm-3, and,
before applying a thermal load annealing the crystal lattice vacancies, introducing atoms of a metallic recombination element into the semiconductor substrate including crystal lattice vacancies.

15. The method according to claim 14, wherein
generating the crystal lattice vacancies comprises performing a rapid thermal anneal in a nitrogen atmosphere.

16. The method according to claim 14, wherein
generating the crystal lattice vacancies comprises performing a rapid thermal anneal after implanting impurities to form a contact zone, wherein during the rapid thermal anneal crystal damages induced by the implant are annealed.

17. The method according to claim 14, wherein
generating the crystal lattice vacancies comprises performing a high temperature process in an inert gas atmosphere containing hydrochloric acid (HCl).

18. The method according to claim 14, wherein
the high temperature process includes an oxidation process in the presence of hydrochloric acid (HCl) and the oxidation process performed before introducing the impurities.

19. The method according to claim 18, comprising:
providing an impurity mask covering sidewalls of a contact groove and exposing a bottom of the contact groove from an oxide layer generated by the oxidation process, and
implanting impurities for forming a contact zone through openings of the impurity mask.

20. The method according to claim 14, comprising:
providing an implant mask covering at least a portion of a cell area of a semiconductor die comprised in the semiconductor substrate and exposing at least a portion of an edge area surrounding the cell area, and
implanting damage particles into exposed portions of the semiconductor die for generating the crystal lattice vacancies.

21. A method of manufacturing a semiconductor device, comprising:
providing an auxiliary mask covering at least a portion of a cell area and exposing at least a portion of an edge area of a semiconductor die comprised in a semiconductor substrate, the edge area surrounding the cell area, and
generating recombination centers in portions of the semiconductor substrate exposed by the auxiliary mask.

22. The method according to claim 21, wherein generating the recombination centers comprises introducing atoms of a metallic recombination element to generate metallic recombination centers in the portions exposed by the auxiliary mask.
